(19) United States
(12) Patent Application Publication
(10) Pub. No.: US 2024/0162021 A1
(43) Pub. Date: May 16, 2024

(54) Sputtering Apparatus

(71) Applicant: Sumitomo Precision Products Co., Ltd., Amagasaki-shi, Hyogo (JP)

(72) Inventor: Yukitaka YAMAGUCHI, Amagasaki-shi (JP)

(21) Appl. No.: 18/283,870

(22) PCT Filed: Feb. 14, 2022
(86) PCT No.: PCT/JP2022/005657

§ 371 Date: Sep. 25, 2023

(30) Foreign Application Priority Data
Mar. 29, 2021 (JP) 2021-055065

(51) Int. Cl. H01J 37/34; C23C 14/02; C23C 14/54

(52) U.S. Cl. CPC H01J 37/3447; C23C 14/021; C23C 14/541; H01J 37/3488

(57) ABSTRACT

A sputtering apparatus (100) according to this invention includes a shutter (50) configured to move between a shutter-closed position (50a) in which the to-be-deposited object (2) is covered from the target (1), and a shutter-moved-out position (50b) in which the shutter is moved out of the shutter-closed position (50a) to an exhaust pump (30) side and stays on the exhaust pump side during thin film deposition. A plate-shaped reflector (60, 70) is arranged between the exhaust pump (30) and the shutter (50) in a moved-out state in which the shutter is arranged at the shutter-moved-out position (50b), and is configured to reflect radiation of heat directing to the exhaust pump (30) from the shutter (50) in the moved-out state.

### TECHNICAL FIELD

The present invention relates to a sputtering apparatus, and in particular to a sputtering apparatus including a shutter configured to cover a to-be-deposited object.

### TECHNICAL FIELD

Sputtering apparatuses including a shutter configured to cover a substrate (to-be-deposited object) are known in the art. Such a sputtering apparatus is disclosed in Japanese Patent Laid-Open Publication No. JP 2002-302763, for example.

The sputtering apparatus described in the above Japanese Patent Laid-Open Publication No. JP 2002-302763, prior to film deposition, oxidation film on a surface of a target placed in a sputter room is removed by sputtering as target cleaning. This sputtering apparatus moves a shutter plate between a substrate holder and the target to cover the substrate from the target in the target cleaning. The shutter plate is then moved to an exhaust chamber side in which a vacuum pump is provided during the film is formed on the substrate.

### PRIOR ART

### Patent Document

Patent Document 1: Japanese Patent Laid-Open Publication No. JP 2002-302763

### SUMMARY OF THE INVENTION

### Problems to be Solved by the Invention

Although not stated in the above Japanese Patent Laid-Open Publication No. JP 2002-302763, the to-be-deposited object (substrate) is heated in the sputtering on some occasions. In such an occasion, the target is heated also during the target cleaning before the film is formed on the substrate. Accordingly, during the target cleaning, the shutter (shutter plate) arranged between the to-be-deposited object and the target is heated simultaneously with the to-be-deposited object. For this reason, when the shutter is moved subsequent to the target cleaning, the shutter moved in the exhaust pump (vacuum pump) side is in a heated state.

In addition, although not stated in the above Japanese Patent Laid-Open Publication No. JP 2002-302763, some of exhaust pumps for exhausting gas from the vacuum chamber (sputter chamber and exhaust chamber) are configured to cool and condense the gas in the vacuum chamber and adsorbing (trapping) the gas in the pump when exhausting the gas. In these exhaust pumps, because the shutter in the heated state is moved to the exhaust pump side, the gas adsorbed in the exhaust pump will be released as impurities into the vacuum chamber by radiation of heat from the shutter in the heated state. Similarly, in a case in which an ion pump or getter pump, which adsorbs gas, is used as the exhaust pump, the gas adsorbed in the exhaust pump will be released into the vacuum chamber by radiation of heat from the heated shutter. Also, in a case in which the exhaust pump is a turbo-molecular pump configured to exhaust gas by collision of gas molecules with a rotor (rotating body) including turbine blades rotating, it is conceivable that members such as the rotor, which make up the exhaust pump, thermally expand due to radiation of heat from the heated shutter. In this case, such thermal expansion of rotating members such as the rotor may bring members, which make up the exhaust pump, into contact with each other, and as result may cause faults of the exhaust pump.

The present invention is intended to solve the above problems, and one object of the present invention is to provide a sputtering apparatus capable of reducing release of gas adsorbed by an exhaust pump into a vacuum chamber even in a case in which a heated shutter is moved to the exhaust pump side, and of preventing faults of the exhaust pump caused by radiation of heat from the heated shutter.

In order to attain the aforementioned object, a sputtering apparatus according to an aspect of the present invention includes a vacuum chamber that is configured to accommodate a to-be-deposited object on which a thin film is deposited by sputtering, and a target from which sputtered particles are ejected to deposit the thin film on the to-be-deposited object; a heater that is configured to heat the to-be-deposited object; an exhaust pump that is configured to exhaust gas in the vacuum chamber; a shutter that is configured to move between a shutter-closed position in which the to-be-deposited object is covered from the target, and a shutter-moved-out position in which the shutter is moved out of the shutter-closed position to the exhaust pump side and stays on the exhaust pump side during the thin film deposition; and a plate-shaped reflector that is arranged between the exhaust pump and the shutter in a moved-out state in which the shutter is arranged at the shutter-moved-out position, and is configured to reflect radiation of heat directing to the exhaust pump from the shutter in the moved-out state.

In the sputtering apparatus according to the aspect of the present invention, as discussed above, a plate-shaped reflector is arranged between the exhaust pump and the shutter in a moved-out state in which the shutter is arranged at the shutter-moved-out position, and is configured to reflect radiation of heat directing to the exhaust pump from the shutter in the moved-out state. Accordingly, the reflector can reflect radiation of heat from the shutter in the moved-out state in which the shutter is arranged at the shutter-moved-out position. Consequently, heat conduction from the heated shutter to the exhaust pump can be reduced. As a result, even when the heated shutter is moved to the exhaust pump side, gas adsorbed in the exhaust pump can be prevented from released into the vacuum chamber. Because heat conduction from the heated shutter to the exhaust pump can be reduced by the reflector, it is possible to prevent contact of members that make up the exhaust pump with each other caused by thermal expansion of the members, which make up the exhaust pump. For this reason, it is possible to prevent faults of the exhaust pump caused by contact of members, which make up the exhaust pump, with each other. Therefore, it is possible reduce release of gas adsorbed by the exhaust pump into the vacuum chamber, and to prevent faults of the exhaust pump caused by radiation of heat from the heated shutter.

In the sputtering apparatus according to the aforementioned aspect, it is preferable that the heater is arranged on one surface side of the shutter in the closed state in which the shutter is arranged at the shutter-closed position; and the reflector is arranged on the one surface side, which is the same side as the heater, with respect to the shutter in the moved-out state in which the shutter is arranged at the shutter-moved-out position. According to this configuration, because the heater and the reflector are arranged on the common one surface side as viewed from the shutter, the reflector can reflect radiation of heat from the one surface side of the shutter heated by the heater. Consequently, conduction of heat radiation from the one surface side of the shutter, which is heated, to the exhaust pump can be effectively prevented, and as a result it is possible effectively reduce release of gas adsorbed by the exhaust pump into the vacuum chamber, and to effectively prevent faults of the exhaust pump.

In the sputtering apparatus according to the aforementioned aspect, it is preferable that a surface of the reflector that faces the shutter in the moved-out state in which the shutter is arranged at the shutter-moved-out position is parallel to a surface of the heater, which is arranged on a side in which the to-be-deposited object is arranged. According to this configuration, even in a case in which the shutter is configured to change from a closed state to the moved-out state by parallel movement from the shutter-closed position to the shutter-moved-out position, the reflector can be positioned along the surface of the shutter heated by the heater. Accordingly, it is possible to effectively reflect radiation of heat from the surface of the shutter heated by the heater. As a result, even in a case in which the shutter is configured to change from the closed state to the moved-out state by parallel movement from the shutter-closed position to the shutter-moved-out position, it is possible effectively reduce release of gas adsorbed by the exhaust pump into the vacuum chamber, and to effectively prevent faults of the exhaust pump. In addition, because the surface of the reflector is parallel to the surface of the heater, radiation of heat from the surface of the shutter can be effectively reflected by the reflector. For this reason, a temperature of the shutter can be kept by reflection of heat by the reflector to a certain temperature, and as a result it is possible to prevent reduction of the temperature of the shutter. Consequently, when the shutter with a temperature reduced in the moved-out state is moved and is positioned in the shutter-closed position again, it is possible to prevent that the temperature reduction of the shutter causes the to-be-deposited object to be insufficiently heated, and therefore it is possible to prevent defects of a deposited thin film. The term “parallel” stated in this specification is used in a broad sense to include a direction slightly inclined from a parallel direction.

In the sputtering apparatus according to the aforementioned aspect, it is preferable that a surface of the reflector on a side that faces the shutter in the moved-out state in which the shutter is arranged at the shutter-moved-out position at least partially includes a mirror finished surface. According to this configuration, because at least part of the surface of the reflector that faces the shutter in the moved-out state is a mirror finished surface, it is possible to more effectively reflect radiation of heat from the shutter in the moved-out state. As a result, heat conduction from the heated shutter to the exhaust pump can be more effectively reduced. Consequently, it is possible more effectively reduce release of gas adsorbed by the exhaust pump into the vacuum chamber, and to more effectively prevent faults of the exhaust pump. Also, because radiation of heat from the shutter in the moved-out state can be more effectively reflected, it is possible to more effectively prevent reduction of a temperature of the shutter. For this reason, it is possible to more effectively prevent adherence of gas in the vacuum chamber on the surface of the shutter caused by reduction of a temperature of the shutter. As a result, it is possible to prevent defects of a thin film deposited on the to-be-deposited object caused by such gas adhering (staying) on the surface of the shutter. In addition, because at least part of the surface of the reflector that faces the shutter in the moved-out state is a mirror finished surface, it is possible to prevent gas from adhering (staying) on the reflector. As a result, it is possible to prevent defects of a thin film deposited on the to-be-deposited object caused by such gas adhering (staying) on the reflector.

In the sputtering apparatus according to the aforementioned aspect, it is preferable that the reflector is configured without being cooled to reflect radiation of heat from the shutter in the moved-out state in which the shutter is arranged at the shutter-moved-out position. According to this configuration, heat conduction from the shutter to the exhaust pump can be easily reduced by reflecting the heat by using the plate-shaped reflector without providing a configuration for cool the reflector such as a refrigerant flow path. As a result, conduction of heat to the exhaust pump can be easily reduced without a complicated configuration. If the reflector is cooled, the temperature of the shutter in the moved-out state in which the shutter is arranged at the shutter-moved-out position is reduced by the cooling of the reflector. To address this, in the present invention, the reflector is configured without being cooled to reflect radiation of heat from the shutter in the moved-out state in which the shutter is arranged at the shutter-moved-out position. According to this configuration, it is possible to prevent reduction of a temperature of the shutter caused by cooling of the reflector. Consequently, it is possible to prevent defects of a thin film deposited on the to-be-deposited object caused by such reduction of a temperature of the shutter.

In the sputtering apparatus according to the aforementioned aspect, it is preferable that the reflector is arranged between an exhaust opening of the vacuum chamber connected to the exhaust pump and the shutter in the moved-out state in which the shutter is arranged at the shutter-moved-out position, and are spaced away from both the exhaust opening and the shutter in the moved-out state. According to this configuration, because the reflector is spaced away from the exhaust opening so that a gap is formed between the reflector and the exhaust opening, it is possible to prevent reduction of exhaust efficiency of the exhaust pump caused by providing the reflector. Accordingly, radiation of heat to the exhaust pump can be effectively reflected by the reflector without reduction of exhaust efficiency. Also, conduction of heat from the shutter in the moved-out state directly to the reflector (direct heat conduction) can be prevented by spacing the reflector away from the shutter in the moved-out state. Accordingly, radiation of heat from the shutter can be reflected without heating reflector itself directly from the shutter, and as a result it is possible to prevent radiation of heat from conducting from the reflector to the exhaust pump when a temperature of the reflector raises. Consequently, it is possible effectively reduce release of gas adsorbed by the exhaust pump into the vacuum chamber, and to effectively prevent faults of the exhaust pump.

In this configuration, it is preferable that the shutter in the moved-out state in which the shutter is arranged at the shutter-moved-out position overlaps the exhaust opening of the vacuum chamber as viewed in a direction orthogonal to a surface of the shutter; and the reflector overlaps the shutter in the moved-out state and the exhaust opening as viewed in a direction orthogonal to a surface of the reflector. According to this configuration in which the reflector overlaps the shutter in the moved-out state and the exhaust opening as viewed in a direction orthogonal to a surface of the reflector, radiation of heat to the exhaust opening from the shutter, which is arranged to overlap the exhaust opening, in the moved-out state can be reflected by the surface of the reflector in the direction orthogonal to the surface of the reflector. Accordingly, as compared with a case in which radiation of heat in a direction other than the direction orthogonal to the surface of the reflector, it is possible to further prevent radiation of heat reflected by the reflector from traveling around the reflector and reaching the exhaust opening side. Consequently, heat conduction to the exhaust pump can be further reduced. The term “orthogonal” stated in this specification is used in a broad sense to include a direction slightly inclined from direction orthogonal to the surface of the reflector.

In the sputtering apparatus in which the reflector overlaps the shutter in the moved-out state and the exhaust opening, it is preferable that a projected area of a surface of the plate-shaped reflector is greater than a projected area of a surface on a side that faces the reflector of the shutter in the moved-out state in which the shutter is arranged at the shutter-moved-out position as viewed in a direction orthogonal to a surface of the shutter. According to this configuration, radiation of heat from a surface of the shutter in the moved-out state can be reflected by the reflector having a projected area greater than the surface of the shutter in the moved-out state. As a result, dissimilar to a case in which the projected area of the reflector is smaller than the shutter, it is possible to reflect heat from the entire surface on the exhaust pump side of the shutter. Consequently, it is possible still further reduce release of gas adsorbed by the exhaust pump into the vacuum chamber, and to still further prevent faults of the exhaust pump.

In this configuration, it is preferable that the reflector has a polygonal or circular plate shape. According to this configuration, in a case in which the reflector has a polygonal plate shape, the reflector can be produced by linearly cutting a sheet metal. Accordingly, the reflector can be more easily produced as compared with a case in which the reflector is produced by cutting a sheet metal along a curved line. On the other hand, because the shutter generally has a circular plate shape, the reflector having a circular plate shape can agree with a shape of the circular-plate-shaped shutter. If a surface area of the reflector is too large, adherence of gas on a surface of the reflector will obstruct high vacuum in the vacuum chamber, and as a result quality of thin film deposited on the to-be-deposited object will deteriorate. Contrary to this, in a case in which the reflector has a circular plate shape, an area of the reflector can be minimized by forming a shape of the reflector corresponding to the shutter while the area of the reflector is larger than an area of the shutter. Accordingly, an amount of gas that is adsorbed on the surface of the reflector can be minimized. Consequently, because an amount of gas that is adsorbed on the surface of the reflector and is released into the vacuum chamber during thin film deposition can be reduced, it is possible prevent deterioration of quality of thin film caused by insufficiently high vacuum. Also, in a case in which the reflector has a circular plate shape, which has no corner, it is possible prevent that thermal stress caused by heat radiated from the shutter is concentratively applied to corners. Consequently, in a case in which the reflector has a circular plate shape, it is possible further prevent deformation of the reflector caused by heat as compared with a case in which the reflector has corners.

In the sputtering apparatus according to the aforementioned aspect, it is preferable that the reflector is arranged parallel to a surface on the exhaust pump side of the shutter in the moved-out state in which the shutter is arranged at the shutter-moved-out position, and faces the surface on the exhaust pump side of the shutter. According to this configuration in which the reflector is arranged parallel to a surface on the exhaust pump side of the shutter in the moved-out state, radiation of heat from the shutter can be reflected in a direction orthogonal to the shutter side. Consequently, it is possible to more effectively prevent radiation of heat from traveling around the reflector and reaching the exhaust opening side, and as a result it is possible to more effectively reduce heat conduction from the shutter to the exhaust pump.

In the sputtering apparatus according to the aforementioned aspect, it is preferable that a plurality of reflectors are provided as the reflector and are spaced away from each other. A temperature of the reflector can be increased by radiation of heat from the shutter on some occasions. In such an occasion, the reflector itself whose temperature is increased becomes a heat source so that radiation of heat is generated toward the exhaust pump from the reflector whose temperature is increased. To address this, the present invention includes the plurality of reflectors spaced away from each other. According to this configuration, even when a temperature of the reflector that is located closer to the shutter in a plurality of reflector is increased, the reflector that is located adjacent to the reflector located closer to the shutter can reflect radiation of heat from the reflector whose temperature is increased. Consequently, even when a temperature of the reflector is increased by radiation of heat from the shutter, conduction of heat to the exhaust pump side can be prevented or slowed by providing a plurality of reflectors as the reflector.

In the sputtering apparatus according to the aforementioned aspect, it is preferable that the exhaust pump is configured to cool gas in the vacuum chamber and then to exhaust the gas; and the reflector is arranged between the exhaust pump, which is configured to cool gas in the vacuum chamber and then to exhaust the gas, and the shutter in the moved-out state in which the shutter is arranged at the shutter-moved-out position. Accordingly, because the reflector can reflect radiation of heat from the shutter in the moved-out state in which the shutter is arranged at the shutter-moved-out position, it is possible to effectively prevent conduction of heat from the heated shutter to the exhaust pump, which is configured to cool gas in the vacuum chamber and then to exhaust the gas. Consequently, it is possible to effectively prevent that heat from the shutter releases gas adsorbed in the exhaust pump into the vacuum chamber.

### Effect of the Invention

According to the present invention, as discussed above, it is possible to provide a sputtering apparatus capable of reducing release of gas adsorbed by an exhaust pump into a vacuum chamber even in a case in which a heated shutter is moved to the exhaust pump side, and of preventing faults of the exhaust pump caused by radiation of heat from the heated shutter.

### BRIEF DESCRIPTION OF THE DRAWINGS

FIG. 1 is a diagram showing a configuration of a sputtering apparatus according to an embodiment of the present invention.

FIG. 2 is a diagram illustrating movement of a shutter between a shutter-closed position and a shutter-moved-out position.

FIGS. 3A to 3B are diagrams illustrating operation of the shutter of the sputtering apparatus, wherein FIG. 3A is the diagram illustrating the shutter in a closed state in which the shutter is positioned at the shutter-closed position, and FIG. 3B is the diagram illustrating the shutter in a moved-out state in which the shutter is positioned at the shutter-moved-out position.

FIG. 4 is a diagram showing two reflectors and the shutter in the moved-out state.

FIG. 5 is a diagram showing an exemplary reflector according to a modified example.

### MODES FOR CARRYING OUT THE INVENTION

Embodiments according the present invention will be described with reference to the drawings.

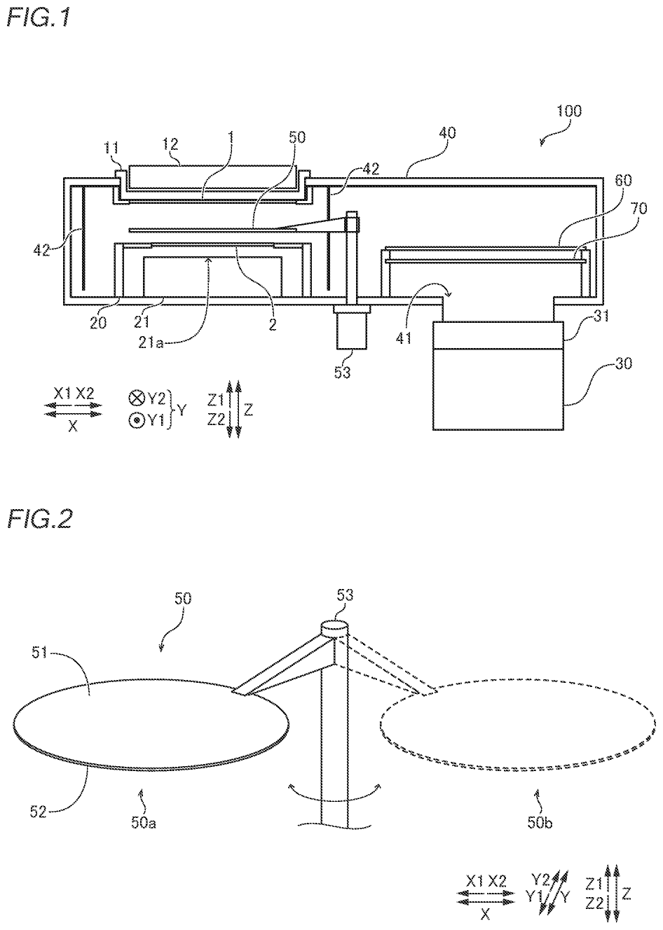

The following description describes a configuration of a sputtering apparatus 100 according to this embodiment with reference to FIGS. 1 to 4.

The sputtering apparatus 100 is configured to eject particles from a target 1 by sputtering so as to deposit a thin film from the sputtered particles ejected from the target 1 subjected to the sputtering on a to-be-deposited object 2. Specifically, the sputtering apparatus 100, for example, introduces gases such as Ar (argon) and O₂ (oxygen) into a vacuum chamber 40, which has been evacuated to a vacuum. The sputtering apparatus 100 then applies a voltage to the target 1 to generate plasma in the vacuum chamber 40. The charged particles in this plasma (for example, argon ions) collide with the target 1 so that the sputtered particles (for example, atoms of the target 1) are ejected from the target 1. The sputtered particles ejected are then adhered (deposited) on to-be-deposited object 2 so that the thin film is formed on a surface of the to-be-deposited object 2.

### Entire Configuration of Sputtering Apparatus

As shown in FIG. 1, the sputtering apparatus 100 includes a cathode electrode 11 and a magnet unit 12. Also, the target 1 is placed in the sputtering apparatus 100.

The target 1 is arranged in the vacuum chamber 40 to generate sputtered particles whereby forming the thin film on the to-be-deposited object 2. In other words, the target 1 is a material of the thin film formed on the to-be-deposited object 2. The target 1 contains, for example, aluminum or copper.

The cathode electrode 11 is connected to a power supply (not shown) and applies a negative charge to the target 1. Specifically, the cathode electrode 11 is configured to generate a plasma discharge phenomenon in the vacuum chamber 40 when a DC high negative voltage is applied to the target 1. The cathode electrode 11 is electrically insulated from the vacuum chamber 40. An alternating voltage, a pulse voltage, or a high-frequency voltage may be applied to the target 1.

The magnet unit 12 is arranged on a back side of the target 1 (a side of the target opposite to a to-be-deposited object 2 side; Z1-direction side). The magnet unit 12 is configured to generate leakage magnetic flux on a surface side of the target 1 (the to-be-deposited object 2 side; Z2-direction side). Due to the leakage magnetic flux (magnetic field) from the magnet unit 12, electrons follow orbits in proximity to the surface of the target 1 on the to-be-deposited object 2 side in the vacuum chamber 40. The sputtering apparatus 100 is configured for magnetron sputtering in which generation of sputtered particles is enhanced by the electrons, which are brought into the orbits by the magnet unit 12.

In addition, the sputtering apparatus 100 includes a mount 20 and a heater 21. The to-be-deposited object 2 is placed on the mount 20 in the vacuum chamber 40. The thin film is formed on the surface of the to-be-deposited object 2 by sputtering. The to-be-deposited object 2 is, for example, a silicon wafer. The mount 20 is configured to be moved upward and downward by an upward/downward moving mechanism such as an electric motor (not shown).

The heater 21 is configured to heat the to-be-deposited object 2 placed on the mount 20. Specifically, the heater 21 has a heating surface 21a extending parallel to an XY plane on a side in which the to-be-deposited object 2 is located (Z1-direction side). The heater 21 is configured to heat a Z2-direction side of the to-be-deposited object 2 placed on the mount 20 with heat from the heating surface 21a. In other words, the heater 21 is configured to heat a side of the to-be-deposited object 2 that is opposite to a side in which the target 1 and the shutter 50 are arranged (on the Z1-direction side). For example, the heater 21 includes a heating wire. The heating surface 21a is an example of a “surface of the heater, which is arranged on a side in which the to-be-deposited object is arranged” in the claims. The heating surface 21a is not limited to a smooth flat surface and may have a peak and trough shape. In this case, a plane connecting peaks of the peak and trough shape of the heating surface 21a is an example of the “surface of the heater, which is arranged on a side in which the to-be-deposited object is arranged” in the claims.

In addition, the sputtering apparatus 100 includes an exhaust pump 30, and an exhaust adjusting valve 31. The exhaust pump 30 is configured to exhaust gas in the vacuum chamber 40. In this embodiment, the exhaust pump 30 is configured to cool gas in the vacuum chamber 40 and then to exhaust the gas. For example, the exhaust pump 30 is a cryopump. The exhaust pump 30 can condense gas in the vacuum chamber 40 by cooling the gas to a low temperature, for example, 100 K (Kelvin) or lower. Also, the exhaust pump 30 is configured to absorb (trap) the condensed gas. The exhaust adjusting valve 31 is configured to adjust a flow rate of the gas exhausted from the exhaust pump 30. In addition, the exhaust adjusting valve 31 is connected to an exhaust opening 41 of the vacuum chamber 40, which will be described later.

The sputtering apparatus 100 has the vacuum chamber 40. The target 1 and the to-be-deposited object 2 are accommodated for sputtering in the vacuum chamber 40. The vacuum chamber 40 is configured to produce a vacuum when the exhaust pump 30 exhausts gas in the vacuum chamber. The target 1 is arranged on the Z1-direction side, and the to-be-deposited object 2 is arranged on the Z2-direction side in the vacuum chamber 40.

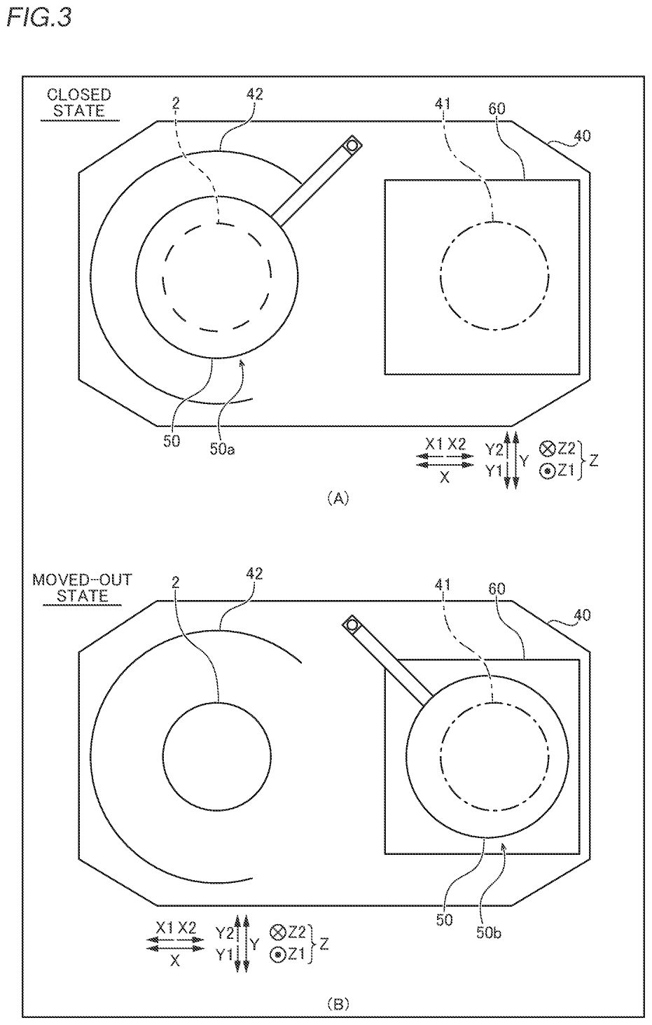

The vacuum chamber 40 has the exhaust opening 41. The exhaust opening 41 is connected to the exhaust pump 30. That is, the exhaust pump 30 is configured to exhaust gas in the vacuum chamber 40 through the exhaust opening 41. The exhaust opening 41 is, for example, a circular opening (see FIG. 3B). The exhaust opening 41 is formed in a part of a bottom surface (Z2-direction side surface) of the vacuum chamber 40 close to the X2-direction side.

In addition, the sputtering apparatus 100 includes an adhesion shield plate 42 in the vacuum chamber 40. The adhesion shield plate 42 is a shield plate for preventing adherence of sputtered particles on inner surfaces of the vacuum chamber 40. The adhesion shield plate 42 is a plate-shaped member having a semi-cylindrical shape (see FIG. 3) extending in a direction in which the target 1 and the to-be-deposited object 2 face each other (Z direction).

### <Configuration of Shutter>

As shown in FIG. 2, the sputtering apparatus 100 includes the shutter 50 and a shutter-driving mechanism 53. The shutter 50 is a disc having an upper surface 51 on the Z1-direction side, and a lower surface 52 on the Z2-direction side. The shutter 50 is formed of stainless steel (SUS304, SUS316), for example. The shutter 50 is configured to cover the to-be-deposited object 2 to prevent adherence of sputter particles from the target 1 on the to-be-deposited object 2. The lower surface 52 is an example of a “one surface”, an example of a “a surface on a side that faces the reflector of the shutter in the moved-out state in which the shutter is arranged at the shutter-moved-out position”, and an example of a “surface on the exhaust pump side of the shutter”.

In the sputtering apparatus 100 according to this embodiment, prior to thin film deposition on the to-be-deposited object 2, oxides on a surface of the target 1 are previously removed by sputtering (target cleaning). In the target cleaning, to prevent adherence (deposition) of sputtered particles on the to-be-deposited object 2 during the target cleaning, the sputtering apparatus 100 covers the to-be-deposited object 2 with the shutter 50 for the sputtering (target 1 cleaning). After the oxidation film on the surface of the target 1 has been removed, the sputtering apparatus 100 moves the shutter 50 out of a position between the target 1 and the to-be-deposited object 2, and then form a thin film on the to-be-deposited object 2 by sputtering.

In this embodiment, the shutter 50 is configured to move between a shutter-closed position 50a in which the to-be-deposited object 2 is covered from the target 1, and a shutter-moved-out position 50b in which the shutter is moved out of the shutter-closed position 50a to the exhaust pump 30 side and stays on the exhaust pump side during the thin film deposition. Specifically, the shutter 50 is moved on the XY plane between the shutter-closed position 50a and the shutter-moved-out position 50b by pivot movement of the shutter-driving mechanism 53 about a pivot axis in parallel to the Z direction.

As shown in FIG. 3, the shutter-closed position 50a is a position of the shutter 50 at which the shutter is arranged between the target 1 and the to-be-deposited object 2 in the vacuum chamber 40. The shutter 50 in a closed state in which the shutter is positioned at the shutter-closed position 50a covers the to-be-deposited object 2 whereby shielding the to-be-deposited object. The shutter-moved-out position 50b is a position of the shutter 50 at which the shutter is moved out of the shutter-closed position 50a to the exhaust pump 30 side. In this embodiment, the shutter 50 in a moved-out state in which the shutter is arranged at the shutter-moved-out position 50b shields (overlaps) the exhaust opening 41 of the vacuum chamber 40 as viewed in a direction orthogonal to (perpendicular to) a surface of the shutter 50. In other words, the shutter 50 in the moved-out state overlaps the exhaust opening 41 as viewed in a direction parallel to the Z direction. The shutter-closed position 50a is a position close to the X1 direction side, while the shutter-moved-out position 50b is a position on the X2 direction side to which the shutter moves from the shutter-closed position 50a in the vacuum chamber 40.

### (Configuration of Reflector)

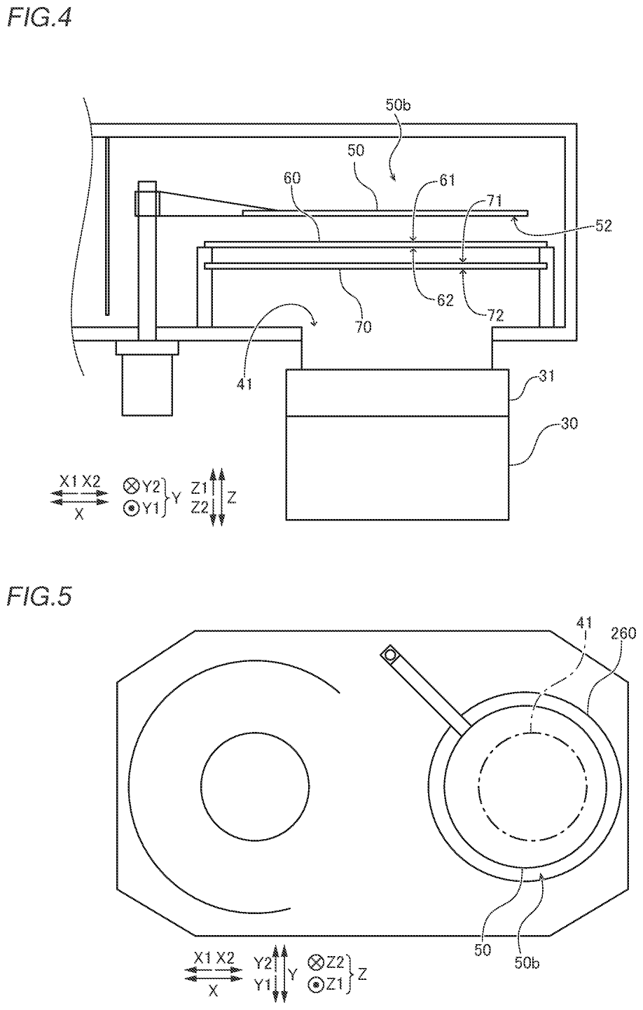

As shown in FIG. 4, the sputtering apparatus 100 according to this embodiment includes two reflectors 60 and 70. The reflectors 60 and 70 are configured to reflect radiation of heat from the shutter 50 in the moved-out state to the exhaust pump 30. The reflectors 60 and 70 have upper surfaces 61 and 71 on the Z1-direction side, respectively, facing the shutter 50 in the moved-out state. The reflectors 60 and 70 have lower surfaces 62 and 72 on the Z2-direction side, respectively. The upper surfaces 61 and 71 are examples of a “surface of the reflector on a side that faces the shutter in the moved-out state in which the shutter is arranged at the shutter-moved-out position” in the claims.

In this embodiment, the reflectors 60 and 70 have a quadrangular plate shape. The reflectors 60 and 70 have a substantially common shape. The reflectors 60 and 70 are formed of stainless steel. The reflectors 60 and 70 may be formed of any material that is impermeable to infrared radiation (heat rays) and has a sufficient thickness to prevent transmission of the infrared radiation. The reflectors 60 and 70 are preferably formed of a material that has high heat resistance and high infrared reflectance on its surface. In this embodiment, surfaces of the reflectors 60 and 70 on a side (Z1-direction side) that faces the shutter 50 in the moved-out state in which the shutter is arranged at the shutter-moved-out position 50b at least partially include a mirror finished surface. Specifically, the upper surfaces 61 and 71 and the lower surfaces 62 and 72 of the two reflectors 60 and 70 are entirely mirror-finished by polishing in order to facilitate reflection of radiation of heat (infrared radiation) and to prevent adherence of gas on the surfaces of the reflectors 60 and 70.

In this embodiment, the reflectors 60 and 70 are configured to reflect radiation of heat from the shutter 50 in the moved-out state in which the shutter is arranged at the shutter-moved-out position 50b without being cooled. In other words, the sputtering apparatus 100 according to this embodiment does not have any structure for cooling the reflectors 60 and 70 (refrigerant flow path, etc.).

### <Arrangement of Reflector>

In this embodiment, the reflectors 60 and 70 are spaced away from each other in the Z direction. The reflectors 60 and 70 face each other, and are arranged parallel to each other (in a parallel direction). Specifically, both the reflectors 60 and 70 are positioned parallel to (in a direction parallel to) the XY plane. In a plan view, the reflectors 60 and 70 are superposed on (overlap) each other.

The reflectors 60 and 70 are arranged to reflect radiation of heat from the lower surface 52 of the shutter 50, which is a surface heated. In this embodiment, the heater 21 is arranged on the lower surface 52 side (Z2-direction side) of the shutter 50 in the closed state in which the shutter is arranged at the shutter-closed position 50a. The reflectors 60 and 70 are arranged on the lower surface 52 side (Z2 direction side), which is the same side as the heater 21, with respect to the shutter 50 in the moved-out state in which the shutter is arranged at the shutter-moved-out position 50b.

In this embodiment, surfaces (upper surface 61 and upper surface 71) of the reflectors 60 and 70 on a side (Z1-direction side) that faces the shutter 50 in the moved-out state in which the shutter is arranged at the shutter-moved-out position 50b is parallel to (arranged in a direction parallel to) a surface (heating surface 21a) of the heater 21, which is arranged on a side (Z1-direction side) in which the to-be-deposited object 2 is arranged. Specifically, the heating surface 21a (a surface on the Z1-direction side), which is a surface of the heater 21 on the to-be-deposited object 2 side, is arranged parallel to the XY plane. The upper surfaces 61 and 71 (surface on the Z1-direction side) of the reflectors 60 and 70 are also arranged parallel to the XY plane.

In this embodiment, the reflectors 60 and 70 are arranged parallel to (in a direction parallel to) the lower surface 52, which is a surface on the exhaust pump 30 side (Z2-direction side) of the shutter 50 in the moved-out state in which the shutter is arranged at the shutter-moved-out position 50b, and faces the lower surface 52, which is the surface on the exhaust pump 30 side of the shutter 50. In other words, both the reflectors 60 and 70 are arranged parallel to, and face the lower surface 52 of the shutter 50 in the moved-out state.

The reflectors 60 and 70 may be deformed in the Z direction by its self-weight, thermal expansion caused by heat radiated from the shutter 50, etc. Although the reflectors 60 and 70 may be deformed, the reflectors 60 and 70, which are arranged parallel to the heating surface 21a in assembling (production) of the sputtering apparatus 100, can be practically used. Similarly, the reflectors 60 and 70, which are arranged parallel to the lower surface 52 of the shutter 50 in the moved-out state in assembling (production) of the sputtering apparatus 100, can be practically used.

In this embodiment, the reflectors 60 and 70 are arranged between the exhaust pump 30 and the shutter 50 in the moved-out state in which the shutter is arranged at the shutter-moved-out position 50b. Specifically, the reflectors 60 and 70 are arranged at a position in which the reflectors cover the exhaust opening 41 from the shutter 50 in the moved-out state in which the shutter is arranged at the shutter-moved-out position 50b. In this embodiment, the reflectors 60 and 70 are arranged between the exhaust opening 41 of the vacuum chamber 40 connected to the exhaust pump 30 and the shutter 50 in the moved-out state in which the shutter is arranged at the shutter-moved-out position 50b, and are spaced away from both the exhaust opening 41 and the shutter 50 in the moved-out state. Specifically, the reflectors 60 and 70 are arranged between the shutter 50 in the moved-out state and the exhaust opening 41 at a position spaced away from both the exhaust opening 41 and the shutter 50 in the Z direction.

As shown in FIG. 3B, in this embodiment, the reflectors 60 and 70 shield (overlap) the shutter 50 in the moved-out state and the exhaust opening 41 as viewed in a direction orthogonal to surfaces of the reflectors 60 and 70 (in a direction parallel to a vertical direction). Specifically, the shutter 50 in the moved-out state overlaps and covers the entire exhaust opening 41 as viewed in the Z direction. Also, the reflectors 60 and 70 overlap and entirely cover the shutter 50 and the exhaust opening 41 as viewed in the Z direction. In this embodiment, a projected area of a surface of each of the plate-shaped reflectors 60 and 70 is greater than a projected area of a surface (lower surface 52) on a side (Z2-direction side) that faces the reflectors 60 and 70 of the shutter 50 in the moved-out state in which the shutter is arranged at the shutter-moved-out position 50b as viewed in a direction (Z direction) orthogonal to a surface (lower surface 52) of the shutter 50. That is, the reflectors 60 and 70 have a size larger than the shutter 50 in the moved-out state as viewed in the Z direction.

### Advantages of the Embodiment

In this embodiment, the following advantages are obtained. In this embodiment, as discussed above, the plate-shaped reflectors 60 and 70 are arranged between the exhaust pump 30 and the shutter 50 in a moved-out state in which the shutter is arranged at the shutter-moved-out position 50b, and are configured to reflect radiation of heat directing to the exhaust pump 30 from the shutter 50 in the moved-out state. Accordingly, the reflectors 60 and 70 can reflect radiation of heat from the shutter 50 in the moved-out state in which the shutter is arranged at the shutter-moved-out position 50b. Consequently, heat conduction from the heated shutter 50 to the exhaust pump 30 can be reduced. As a result, even when the heated shutter 50 is moved to the exhaust pump 30 side, gas adsorbed in the exhaust pump 30 can be prevented from released into the vacuum chamber 40.

In this embodiment, as discussed above, the heater 21 is arranged on the lower surface 52 (one surface) side of the shutter 50 in the closed state in which the shutter is arranged at the shutter-closed position 50a; and the reflectors 60 and 70 are arranged on the lower surface 52 (one surface) side, which is the same side as the heater 21, with respect to the shutter 50 in the moved-out state in which the shutter is arranged at the shutter-moved-out position 50b. Accordingly, because the heater 21 and the reflectors 60 and 70 are arranged on the common lower surface 52 (one surface) side as viewed from the shutter 50, the reflectors 60 and 70 can reflect radiation of heat from the lower surface 52 (one surface) side of the shutter 50 heated by the heater 21. Consequently, conduction of heat radiation from the lower surface 52 (one surface) side of the shutter 50, which is heated, to the exhaust pump 30 can be prevented, and as a result it is possible effectively reduce release of gas adsorbed by the exhaust pump 30 into the vacuum chamber 40.

In this embodiment, as discussed above, surfaces (upper surfaces 61 and 71) of the reflectors 60 and 70 on a side (Z1-direction side) that faces the shutter 50 in the moved-out state in which the shutter is arranged at the shutter-moved-out position 50b is parallel to a surface of the heater 21, which is arranged on a side (Z1-direction side) in which the to-be-deposited object 2 is arranged. Accordingly, even in a case in which the shutter 50 is configured to change from the closed state to the moved-out state by parallel movement from the shutter-closed position 50a to the shutter-moved-out position 50b, the reflectors 60 and 70 can be positioned along the surface (lower surface 52) of the shutter 50 heated by the heater 21. For this reason, it is possible to effectively reflect radiation of heat from the surface (lower surface 52) of the shutter 50 heated by the heater 21. As a result, even in a case in which the shutter 50 is configured to change from the closed state to the moved-out state by parallel movement from the shutter-closed position 50a to the shutter-moved-out position 50b, it is possible effectively reduce release of gas adsorbed by the exhaust pump 30 into the vacuum chamber 40. In addition, because the surfaces (upper surfaces 61 and 71) of the reflectors 60 and 70 are parallel to the surface (heating surface 21a) of the heater 21, radiation of heat from the surface (lower surface 52) of the shutter 50 can be effectively reflected by the reflectors 60 and 70. For this reason, a temperature of the shutter 50 can be kept by reflection of heat by the reflectors 60 and 70 to a certain temperature, and as a result it is possible to prevent reduction of the temperature of the shutter 50. Consequently, when the shutter 50 with a temperature reduced in the moved-out state is moved and is positioned in the shutter-closed position 50a again, it is possible to prevent that the temperature reduction of the shutter 50 causes the to-be-deposited object 2 to be insufficiently heated, and therefore it is possible to prevent defects of a deposited thin film.

In this embodiment, as discussed above, the surfaces (upper surfaces 61 and 71) of the reflectors 60 and 70 on a side (Z1-direction side) that faces the shutter 50 in the moved-out state in which the shutter is arranged at the shutter-moved-out position 50b are entirely mirror-finished. Accordingly, because the surfaces (upper surfaces 61 and 71) of the reflectors 60 and 70 that face the shutter 50 in the moved-out state are at least partially mirror-finished, it is possible to more effectively reflect radiation of heat from the shutter 50 in the moved-out state. As a result, heat conduction from the heated shutter 50 to the exhaust pump 30 can be more effectively reduced. Consequently, it is possible more effectively reduce release of gas adsorbed by the exhaust pump 30 into the vacuum chamber 40. Also, because radiation of heat from the shutter 50 in the moved-out state can be more effectively reflected, it is possible to more effectively prevent reduction of a temperature of the shutter 50. For this reason, it is possible to more effectively prevent adherence of gas in the vacuum chamber 40 on the surface of the shutter 50 caused by reduction of a temperature of the shutter 50. As a result, it is possible to prevent defects of a thin film deposited on the to-be-deposited object 2 caused by such gas adhering (staying) on the surface of the shutter 50. In addition, because the surfaces (upper surfaces 61 and 71) of the reflectors 60 and 70 that face the shutter 50 in the moved-out state are at least partially mirror-finished, it is possible to prevent gas from adhering (staying) on the reflectors 60 and 70. As a result, it is possible to prevent defects of a thin film deposited on the to-be-deposited object 2 caused by such gas adhering (staying) on the reflectors 60 and 70.

In this embodiment, as discussed above, the reflectors 60 and 70 are configured to reflect radiation of heat from the shutter 50 in the moved-out state in which the shutter is arranged at the shutter-moved-out position 50b without being cooled. Accordingly, conduction of heat from the shutter 50 to the exhaust pump 30 can be easily reduced by reflecting the heat by using the plate-shaped reflectors 60 and 70 without providing a configuration for cool the reflectors 60 and 70 such as a refrigerant flow path. As a result, conduction of heat to the exhaust pump 30 can be easily reduced without a complicated configuration. If the reflectors 60 and 70 are cooled, the temperature of the shutter 50 in the moved-out state in which the shutter is arranged at the shutter-moved-out position 50b is reduced by the cooling of the reflectors 60 and 70. To address this, in this embodiment, the reflectors 60 and 70 are configured without being cooled to reflect radiation of heat from the shutter 50 in the moved-out state in which the shutter is arranged at the shutter-moved-out position 50b. Accordingly, it is possible to prevent reduction of a temperature of the shutter 50 caused by cooling of the reflectors 60 and 70. Consequently, it is possible to prevent defects of a thin film deposited on the to-be-deposited object 2 caused by such reduction of a temperature of the shutter 50.

In this embodiment, as discussed above, the reflectors 60 and 70 are arranged between the exhaust opening 41 of the vacuum chamber 40 connected to the exhaust pump 30 and the shutter 50 in the moved-out state in which the shutter is arranged at the shutter-moved-out position 50b, and are spaced away from both the exhaust opening 41 and the shutter 50 in the moved-out state. Accordingly, because the reflectors 60 and 70 are spaced away from the exhaust opening 41 so that a gap is formed between the reflectors 60 and 70, and the exhaust opening 41, it is possible to prevent reduction of exhaust efficiency of the exhaust pump 30 caused by providing the reflectors 60 and 70. Accordingly, radiation of heat to the exhaust pump 30 can be effectively reflected by the reflectors 60 and 70 without reduction of exhaust efficiency. Also, conduction of heat from the shutter 50 in the moved-out state directly to the reflectors 60 and 70 (direct heat conduction) can be prevented by spacing the reflectors 60 and 70 away from the shutter 50 in the moved-out state. Accordingly, radiation of heat from the shutter 50 can be reflected without heating reflectors 60 and 70 themselves directly from the shutter 50, and as a result it is possible to prevent radiation of heat from conducting from the reflectors 60 and 70 to the exhaust pump 30 when temperatures of the reflectors 60 and 70 raise. Consequently, it is possible effectively reduce release of gas adsorbed by the exhaust pump 30 into the vacuum chamber 40.

In this embodiment, as discussed above, the shutter 50 in the moved-out state in which the shutter is arranged at the shutter-moved-out position 50b overlaps the exhaust opening 41 of the vacuum chamber 40 as viewed in a direction (Z direction) orthogonal to a surface of the shutter 50; and the reflectors 60 and 70 overlap the shutter 50 in the moved-out state and the exhaust opening 41 as viewed in a direction (Z direction) orthogonal to surfaces of the reflectors 60 and 70. Accordingly, because the reflectors 60 and 70 overlap the shutter 50 in the moved-out state and the exhaust opening 41 as viewed in the direction (Z direction) orthogonal to the surfaces of the reflectors 60 and 70, radiation of heat to the exhaust opening 41 from the shutter 50, which is arranged to overlap the exhaust opening 41, in the moved-out state can be reflected by the surfaces of the reflectors 60 and 70 in the direction (Z direction) orthogonal to the surfaces of the reflectors. As a result, as compared with a case in which radiation of heat in a direction other than the direction orthogonal to the surfaces of the reflectors 60 and 70, it is possible to further prevent radiation of heat reflected by the reflectors 60 and 70 from traveling around the reflectors and reaching the exhaust opening 41 side. Consequently, heat conduction to the exhaust pump 30 can be further reduced.

In this embodiment, as discussed above, a projected area of a surface of each of the plate-shaped reflectors 60 and 70 is greater than a projected area of a surface (lower surface 52) on a side (Z2-direction side) that faces the reflectors 60 and 70 of the shutter 50 in the moved-out state in which the shutter is arranged at the shutter-moved-out position 50b as viewed in a direction orthogonal to a surface (lower surface 52) of the shutter 50. Accordingly, radiation of heat from a surface (lower surface 52) of the shutter 50 in the moved-out state can be reflected by the reflectors 60 and 70 having a projected area greater than the surface of the shutter 50 in the moved-out state. As a result, dissimilar to a case in which the projected area of each of the reflectors 60 and 70 is smaller than the shutter 50, it is possible to reflect heat from the entire surface (lower surface 52) on the exhaust pump 30 side (Z2-direction side) of the shutter 50. Consequently, it is possible still further reduce release of gas adsorbed by the exhaust pump 30 into the vacuum chamber 40.

In this embodiment, as discussed above, the reflectors 60 and 70 have a polygonal (quadrangular) plate shape. Accordingly, in a case in which the reflectors 60 and 70 have a quadrangular plate shape, the reflectors 60 and 70 can be produced by linearly cutting a sheet metal. As a result, the reflectors 60 and 70 can be more easily produced as compared with a case in which the reflectors are produced by cutting a sheet metal along a curved line.

In this embodiment, as discussed above, the reflectors 60 and 70 are arranged parallel to a surface (lower surface 52) on the exhaust pump 30 side (Z2-direction side) of the shutter 50 in the moved-out state in which the shutter is arranged at the shutter-moved-out position 50b, and faces the surface (lower surface 52) on the exhaust pump 30 side of the shutter 50. Accordingly, because the reflectors 60 and 70 are arranged parallel to the surface (lower surface 52) on the exhaust pump 30 side of the shutter 50 in the moved-out state, radiation of heat from the shutter 50 can be reflected in a direction orthogonal to the shutter 50 side. Consequently, it is possible to more effectively prevent radiation of heat from traveling around the reflectors and reaching the exhaust opening 41 side, and as a result it is possible to more effectively reduce heat conduction from the shutter 50 to the exhaust pump 30.

In this embodiment, as discussed above, a plurality of reflectors 60 and 70 are spaced away from each other. Temperatures of the reflectors 60 and 70 may be increased by radiation of heat from the shutter 50. In this case, the reflectors 60 and 70 themselves whose temperature is increased becomes a heat source so that radiation of heat is generated toward the exhaust pump 30 from the reflectors 60 and 70 whose temperature is increased. To address this, in this embodiment, the plurality of reflectors 60 and 70 are spaced away from each other. Accordingly, even when a temperature of the reflector 60, which is located closer to the shutter 50 in the plurality of reflectors 60 and 70, is increased, the reflector 70, which is located adjacent to the reflector located closer to the shutter, can reflect radiation of heat from the reflector 60 whose temperature is increased. Consequently, even when a temperature of the reflector 60 is increased by radiation of heat from the shutter 50, conduction of heat to the exhaust pump 30 side can be prevented or slowed by providing a plurality of reflectors 60 and 70 as the reflector.

In this embodiment, as discussed above, the exhaust pump 30 is configured to cool gas in the vacuum chamber 40 and then to exhaust the gas; and the reflectors 60 and 70 are arranged between the exhaust pump 30, which is configured to cool gas in the vacuum chamber 40 and then to exhaust the gas, and the shutter 50 in the moved-out state in which the shutter is arranged at the shutter-moved-out position 50b. Accordingly, because the reflectors 60 and 70 can reflect radiation of heat from the shutter 50 in the moved-out state in which the shutter is arranged at the shutter-moved-out position 50b, it is possible to effectively prevent conduction of heat from the heated shutter 50 to the exhaust pump 30, which is configured to cool gas and then to exhaust the gas. Consequently, it is possible to effectively prevent that heat from the shutter 50 releases gas adsorbed in the exhaust pump 30 into the vacuum chamber 40.

### Modified Embodiment

Note that the embodiment disclosed this time must be considered as illustrative in all points and not restrictive. The scope of the present invention is not shown by the above description of the embodiments but by the scope of claims for patent, and all modifications within the meaning and scope equivalent to the scope of claims for patent are further included.

While the example in which both the heater 21 and a set of the reflectors 60 and 70 are arranged on the lower surface 52 side (Z2 direction side) of the shutter 50 in the moved-out state has been shown in the aforementioned embodiment, the present invention is not limited to this. In the present invention, the heater 21 and the set of the reflectors 60 and 70 may be arranged on the upper surface 51 side and the lower surface 52 side of the shutter 50, respectively. In this case, the reflectors 60 and 70 are arranged on a side in which the exhaust opening 41 is arranged as viewed from the shutter 50.

While the example in which the upper surfaces 61 and 71 of the reflectors 60 and 70 are parallel to the heating surface 21a of the heater 21 has been shown in the aforementioned embodiment, the present invention is not limited to this. For example, the upper surfaces 61 and 71 of the reflectors 60 and 70 may be arranged in a positional relationship in which they intersect the heating surface 21a of the heater 21.

While the example in which the lower surface 52 of the shutter 50 in the closed state in which the shutter is arranged at the shutter-closed position 50a is parallel to the heating surface 21a of the heater 21 has been shown in the aforementioned embodiment, the present invention is not limited to this. For example, in a case in which a thin film is formed by sputtering in a slant direction with respect to a direction orthogonal to a surface of the to-be-deposited object 2, the shutter 50 may be arranged in a slant orientation with respect to the surface of the to-be-deposited object 2. In this case, the heating surface 21a of the heater 21 may be arranged parallel to the surface of the to-be-deposited object 2 so that the shutter 50 may be arranged not in parallel to the heating surface 21a of the heater 21 but in a slant orientation with respect to the heating surface.

While the example in which both surfaces of each of the reflectors 60 and 70 are mirror-finished has been shown in the aforementioned embodiment, the present invention is not limited to this. For example, one surface of each of the reflectors 60 and 70 may be mirror-finished. Also, only a part of the one surface may be mirror-finished. Also, only one of the reflectors 60 and 70 may be mirror-finished. Also, in the present invention, both the reflectors 60 and 70 may have no mirror finished surface. Also, the reflectors 60 and 70 may be subjected to surface finishing that is unperceivable in the visible light range (human eyes cannot recognize their surfaces as a mirror finished surface) but reduces infrared absorption and increases infrared reflectance. A means for mirror finishing is not limited to polishing. In other words, the surfaces of the reflectors 60 and 70 may be subjected to treatment that coats the surfaces with a material other than stainless steel to effectively reflect radiation of heat from the shutter 50.

While the example in which the reflectors 60 and 70 are spaced away from both the exhaust opening 41 and the shutter 50 has been shown in the aforementioned embodiment, the present invention is not limited to this. For example, the reflectors 60 and 70 may be in contact with the exhaust opening 41.

While the example in which the shutter 50 in a moved-out state in which the shutter is arranged at the shutter-moved-out position 50b shields (overlaps) the exhaust opening 41 as viewed in a direction (Z direction) orthogonal to a surface of the shutter 50 has been shown in the aforementioned embodiment, the present invention is not limited to this. For example, the shutter 50 in the moved-out state may not shield (overlap) the exhaust opening 41 as viewed in the direction orthogonal to the surface of the shutter 50. In this case, the reflectors 60 and 70 may shield (overlap) the shutter 50 in the moved-out state, or the exhaust opening 41 may shield (overlap) the reflectors 60 and 70. In other words, the reflectors 60 and 70 are only required to hide (shield) the shutter 50 from the exhaust opening 41.

While the example in which a projected area of a surface of each of the plate-shaped reflectors 60 and 70 is greater than a projected area of a surface (lower surface 52) on a side (Z2-direction side) that faces the reflectors 60 and 70 of the shutter 50 in the moved-out state has been shown in the aforementioned embodiment, the present invention is not limited to this. For example, a projected area of the surface of the reflector 60 or 70 may be smaller than the area of the surface (lower surface 52) on the side (Z2-direction side), which faces the reflectors 60 and 70, of the shutter 50. In other words, a projected area of at least one of a plurality of reflectors may be greater than the projected area of the shutter 50, and a projected area of each of other reflectors may be smaller than the shutter 50. Alternatively, a plurality of reflectors smaller than the shutter 50 may be combined to provide a total projected area of the reflectors larger than the shutter 50.

While the example in which the reflectors 60 and 70 have a quadrangular (rectangular) plate shape has been shown in the aforementioned embodiment, the present invention is not limited to this. For example, reflectors 60 and 70 may be have a polygonal plate shape such as a triangular or pentagonal plate shape. In addition, the reflectors 60 and 70 may have a rib for preventing their deformation on their back surface. The reflectors 60 and 70 may be formed of a deformable (flexible) sheet or film.

A reflector 260 may have a circular plate shape as the reflector 260 according to a modified example shown in FIG. 5. Because the shutter 50 typically has a circular plate shape, the reflector 260 having a circular plate shape can agree with a shape of the circular-plate-shaped shutter 50. If a surface area of the reflector 260 is too large, adherence of gas on a surface of the reflector 260 will obstruct high vacuum in the vacuum chamber 40, and as a result quality of thin film deposited on the to-be-deposited object 2 will deteriorate. Contrary to this, in a case in which the reflector 260 has a circular plate shape, an area of the reflector 260 can be minimized by forming a shape of the reflector corresponding to the shutter 50 while the area of the reflector 260 is larger than an area of the shutter 50. Accordingly, an amount of gas that is adsorbed on the surface of the reflector 260 can be minimized. Consequently, because an amount of gas that is adsorbed on the surface of the reflector 260 and is released into the vacuum chamber 40 during thin film deposition can be reduced, it is possible prevent deterioration of quality of thin film caused by insufficiently high vacuum. Also, in a case in which the reflector 260 has a circular plate shape, which has no corner, it is possible prevent that thermal stress caused by heat radiated from the shutter 50 is concentratively applied to corners. Consequently, in a case in which the reflector 260 has a circular plate shape, it is possible further prevent deformation of the reflector caused by heat as compared with a case in which the reflector 260 has corners.

While the example in which the reflectors 60 and 70 are arranged parallel to the lower surface 52 of the shutter 50 in the moved-out state, and faces the lower surface 52 of the shutter 50 has been shown in the aforementioned embodiment, the present invention is not limited to this. For example, the reflector 60 and the reflector 70 may be arranged not parallel to the lower surface 52 of the shutter 50 but to be inclined with respect to the lower surface of the shutter while facing the lower surface of the shutter.

While the example in which two reflectors 60 and 70 are spaced away from each other has been shown in the aforementioned embodiment, the present invention is not limited to this. For example, one reflector, or three or more reflectors may be provided. Two or more reflectors may be formed of different materials.

While the example in which two reflectors 60 and 70 are arranged parallel to each other has been shown in the aforementioned embodiment, the present invention is not limited to this. Two (or more) reflectors may be arranged not parallel to each other but to be inclined with respect to each other while facing each other.

While the example in which two reflectors 60 and 70 have a substantially common shape has been shown in the aforementioned embodiment, the present invention is not limited to this. For example, two reflectors may have different shapes from each other. That is, one of the two reflectors may have a quadrangular (polygonal) shape, while another have a circular shape. The reflector 70 may have an area larger than the reflector 60.

While the example in which the shutter 50 is used to remove oxides on a surface of the target 1 (for target cleaning) has been shown in the aforementioned embodiment, the present invention is not limited to this. The shutter 50 may be positioned at the shutter-closed position in sputtering without forming a thin film on the to-be-deposited object 2 such as stabilization of plasma (discharging), stabilization of an atmosphere in the vacuum chamber 40, etc., other than target cleaning, for example.

While the example in which the shutter 50 has a circular plate shape has been shown in the aforementioned embodiment, the present invention is not limited to this. The shutter 50 may have a polygonal shape such as a rectangular shape.

While the example in which the shutter 50 in the moved-out state has an area greater than an opening area of the exhaust opening 41 has been shown in the aforementioned embodiment, the present invention is not limited to this. For example, the area of the shutter 50 may be smaller than the opening area of the exhaust opening 41. In this case, the reflectors 60 and 70 may also have an area smaller than the exhaust opening 41.

While the example in which the shutter 50 is configured to change from the closed state to the moved-out state by parallel movement from the shutter-closed position 50a to the shutter-moved-out position 50b has been shown in the aforementioned embodiment, the present invention is not limited to this. For example, the shutter 50 may be configured to change its shape between the moved-out state at the shutter-closed position 50a and the closed state at the shutter-moved-out position 50b. That is, the shutter 50 may be configured to change its shape between a single plate shape in the moved-out state at the shutter-closed position 50a and a folded shape in the closed state at the shutter-moved-out position 50b.

While the example in which the exhaust pump 30 is a cryopump configured to cool gas in the vacuum chamber 40 and then to exhaust the gas has been shown in the aforementioned embodiment, the present invention is not limited to this. For example, the exhaust pump, which is configured to exhaust in the vacuum chamber 40, may be an ion pump or a getter pump configured to adsorb gas. Also, in this case, even when the heated shutter is moved to the exhaust pump side, gas adsorbed in the exhaust pump can be prevented from released into the vacuum chamber. The exhaust pump may be a turbo-molecular pump configured to exhaust gas by collision of gas molecules with a rotor (rotating body) including turbine blades rotating. Also, in this case, because heat conduction from the heated shutter to the exhaust pump can be reduced by the reflector, it is possible to prevent contact of members that make up the exhaust pump with each other caused by thermal expansion of the members, which make up the exhaust pump. As a result, it is possible to prevent faults of the exhaust pump caused by contact of members, which make up the exhaust pump, with each other.

### Description of Reference Numerals

1; target

2; to-be-deposited object

21; heater

21a; heating surface (surface of heater on side in which to-be-deposited object is arranged)

30; exhaust pump

40; vacuum chamber

41; exhaust opening

50; shutter

50a; shutter-closed position

50b; shutter-moved-out position

52; lower surface (one surface, surface on side that faces reflector, surface on exhaust pump side)

60, 70, 260; reflector (a plurality of reflectors)

61, 71; upper surface (surface on side that faces shutter in moved-out state in which shutter is arranged at shutter-moved-out position)

100; sputtering apparatus

1. A sputtering apparatus comprising:
a vacuum chamber that is configured to accommodate a to-be-deposited object on which a thin film is deposited by sputtering, and a target from which sputtered particles are ejected to deposit the thin film on the to-be-deposited object;
a heater that is configured to heat the to-be-deposited object;
an exhaust pump that is configured to exhaust gas in the vacuum chamber;
a shutter that is configured to move between a shutter-closed position in which the to-be-deposited object is covered from the target, and a shutter-moved-out position in which the shutter is moved out of the shutter-closed position to the exhaust pump side and stays on the exhaust pump side during the thin film deposition; and
a plate-shaped reflector that is arranged between the exhaust pump and the shutter in a moved-out state in which the shutter is arranged at the shutter-moved-out position, and is configured to reflect radiation of heat directing to the exhaust pump from the shutter in the moved-out state.

2. The sputtering apparatus according to claim 1, wherein
the heater is arranged on one surface side of the shutter in the closed state in which the shutter is arranged at the shutter-closed position; and
the reflector is arranged on the one surface side, which is the same side as the heater, with respect to the shutter in the moved-out state in which the shutter is arranged at the shutter-moved-out position.

3. The sputtering apparatus according to claim 1, wherein a surface of the reflector on a side that faces the shutter in the moved-out state in which the shutter is arranged at the shutter-moved-out position is parallel to a surface of the heater, which is arranged on a side in which the to-be-deposited object is arranged.

4. The sputtering apparatus according to claim 1, wherein a surface of the reflector on a side that faces the shutter in the moved-out state in which the shutter is arranged at the shutter-moved-out position at least partially includes a mirror finished surface.

5. The sputtering apparatus according to claim 4, wherein the reflector is configured without being cooled to reflect radiation of heat from the shutter in the moved-out state in which the shutter is arranged at the shutter-moved-out position.

6. The sputtering apparatus according to claim 1, wherein the reflector is arranged between an exhaust opening of the vacuum chamber connected to the exhaust pump and the shutter in the moved-out state in which the shutter is arranged at the shutter-moved-out position, and is spaced away from both the exhaust opening and the shutter in the moved-out state.

7. The sputtering apparatus according to claim 6, wherein
the shutter in the moved-out state in which the shutter is arranged at the shutter-moved-out position overlaps the exhaust opening of the vacuum chamber as viewed in a direction orthogonal to a surface of the shutter; and
the reflector overlaps the shutter in the moved-out state and the exhaust opening as viewed in a direction orthogonal to a surface of the reflector.

8. The sputtering apparatus according to claim 7, wherein a projected area of a surface of the plate-shaped reflector is greater than a projected area of a surface on a side that faces the reflector of the shutter in the moved-out state in which the shutter is arranged at the shutter-moved-out position as viewed in a direction orthogonal to a surface of the shutter.

9. The sputtering apparatus according to claim 8, wherein the reflector has a polygonal or circular plate shape.

10. The sputtering apparatus according to claim 1, wherein the reflector is arranged parallel to a surface on the exhaust pump side of the shutter in the moved-out state in which the shutter is arranged at the shutter-moved-out position, and faces the surface on the exhaust pump side of the shutter.

11. The sputtering apparatus according to claim 1, wherein a plurality of reflectors are provided as the reflector and are spaced away from each other.

12. The sputtering apparatus according to claim 1, wherein
the exhaust pump is configured to cool gas in the vacuum chamber and then to exhaust the gas; and
the reflector is arranged between the exhaust pump, which is configured to cool gas in the vacuum chamber and then to exhaust the gas, and the shutter in the moved-out state in which the shutter is arranged at the shutter-moved-out position.
